(19) United States
(12) Patent Application Publication
(10) Pub. No.: US 2025/0231114 A1
(43) Pub. Date: Jul. 17, 2025

(54) IMAGE SENSOR WITH OXIDE FREE WAFER BONDED STRUCTURES AND METHODS FOR FABRICATING IMAGE SENSORS

(71) Applicant: KLA Corporation, Milpitas, CA (US)

(72) Inventors: Yajun Wei, Milpitas, CA (US); Sisir Yalamanchili, Milpitas, CA (US); Devis Contarato, Milpitas, CA (US); John Fielden, Los Altos, CA (US); Yung-Ho Alex Chuang, Cupertino, CA (US)

(21) Appl. No.: 18/978,351

(22) Filed: Dec. 12, 2024

Related U.S. Application Data
(60) Provisional application No. 63/621,594, filed on Jan. 17, 2024.

(51) Int. Cl. G01N 21/88; H01L 21/67

(52) U.S. Cl. CPC G01N 21/8806; H01L 21/67288

(57) ABSTRACT

An image sensor and method for fabricating an image sensor. In embodiments, first and second wafers are independently processed with each wafer including part of the final sensor structure. The two wafers are bonded together by an oxide-free wafer bond to form a hybrid wafer combining the two partial sensor structures into one fully functional sensor structure connected by an oxide-free bonding interface enabling continuity of charge transport and minimizing signal loss. Each of the first and second sensor wafers may be fabricated at its optimal process conditions such that the combined sensor can have enhanced sensor capabilities such as quantum efficiency, gain, wavelength range, etc. In embodiments, the first and second sensor wafers may be fabricated in parallel to maximize production throughput.

### CROSS REFERENCE TO RELATED APPLICATION

This nonprovisional application claims the benefit of priority of U.S. Provisional Application No. 63/621,594 filed Jan. 17, 2024 for IMAGE SENSOR WITH OXIDE FREE BONDED STRUCTURES FOR INSPECTION AND METROLOGY, which is hereby incorporated by reference in its entirety.

### TECHNICAL FIELD

The present disclosure relates generally to image sensors for sensing radiation at, for example, visible, ultraviolet (UV), deep UV (DUV), vacuum UV (VUV), extreme UV (EUV), and X-ray wavelengths, and for sensing electrons or other charged particles, and to methods for fabricating image sensors. The image sensors may be used in inspection systems, including those used to inspect photomasks, reticles, and semiconductor wafers.

### BACKGROUND

The integrated circuit industry requires inspection tools that provide increasingly higher sensitivity to detect smaller defects and particles while maintaining high throughput. The semiconductor industry is currently manufacturing semiconductor devices with feature dimensions in the nanometer scale. Particles and defects just a few nm in size can impact wafer yields and therefore must be captured to assist maximizing yield and minimizing production cost. Furthermore, efforts have been spent on increasing inspection speed to accommodate the transition from 300 mm wafers of today to 450 mm wafers in the future. Thus, the semiconductor industry is driven by ever greater demand for inspection tools that can achieve high sensitivity at high speed.

An image sensor is a key component of a semiconductor inspection tool and plays an important role in determining defect detection sensitivity and inspection speed. Considering their image quality, light sensitivity, and readout noise performance, a charge-coupled-device (CCD) or a complementary metal-oxide semiconductor (CMOS) is widely used as image sensors for semiconductor inspection applications. With CCD image sensors, critical performance parameters include signal-to-noise-ratio (SNR) and dynamic range (DR), where SNR describes the ability of the sensor to detect a light signal above a certain noise-limited background, and DR quantifies the ability of the sensor to adequately image both high light and low light scenes.

Silicon-based image sensors typically employ bulk silicon as the absorber material, and a reverse biased pn junction to sweep the collected charge and convert the same into a voltage signal that may be buffered and/or amplified and converted into a digital signal. The silicon sensing structure is an integral part of the on-chip circuitry that is processed together, either as a frontside illuminated or backside illuminated architecture. Frontside illumination has its limitation in the optical fill factor due to the presence of optically reflective or absorptive elements required to convert photons into electrical signals, such as metals, polysilicon, etc., leading to limited sensitivity. Therefore, the most sensitive silicon-based sensors usually employ a backside illumination architecture with full depletion to ensure high carrier collection efficiency and high sensor modulation transfer function (MTF).

While moving towards shorter and shorter UV wavelengths as required for smaller and smaller feature detection, it has become increasingly challenging to achieve higher and higher sensitivity due to shallow absorption depths for light of such wavelengths and carrier recombination at the surface. Combining the sensing structures and the circuitries in the same wafer process flow can lead to certain process limitations that impact sensor performance. For example, the best surface passivation may require a process temperature that may degrade or destroy circuitry elements thus limiting the implementation of detector architectures such as high temperature surface passivation, or incorporating another wider bandgap material such as BN, AlN, Al₂O₃, GaN, etc.

Therefore, there is a need to separately process either partial or entire detector structures independently and then combine them with the main sensor wafer afterwards to achieve improved sensor performance and capability.

### SUMMARY

According to a first aspect, the present disclosure is directed to a method for fabricating an image sensor. In embodiments, the method includes fabricating a first sensor wafer including first sensor structure and a temporarily bonded first carrier wafer, fabricating a second sensor wafer including second sensor structure and a temporarily bonded second carrier wafer, processing each of the first and second sensor wafers for bonding, and bonding the first and second sensor wafers by an electrically conductive oxide-free wafer bond to form an integral sensor wafer.

In some embodiments, fabricating the first sensor wafer includes forming a first epitaxial silicon layer on a first silicon wafer substrate, forming the first sensor structure on a front side of the first epitaxial silicon layer, and temporarily bonding the first carrier wafer to the front side of the first epitaxial silicon layer including the first sensor structure, and fabricating the second sensor wafer includes forming a second epitaxial silicon layer on a second silicon wafer substrate, forming the second sensor structure on a front of the second epitaxial silicon layer, and temporarily bonding the second carrier wafer to the front side of the second epitaxial silicon layer including the second sensor structure.

In some embodiments, processing the sensor wafer for bonding includes thinning the first silicon wafer substrate to expose a back side of the first epitaxial silicon layer, and polishing the back side of the first epitaxial silicon layer to obtain a flat bonding surface, and processing the second sensor wafer for bonding includes thinning the second silicon wafer substrate to expose a back side of the second epitaxial silicon layer, and polishing the back side of the second epitaxial silicon layer to obtain a flat bonding surface.

In some embodiments, processing the first and second sensor wafers for bonding further includes subjecting the polished back side of the first epitaxial silicon layer and the polished back side of the second epitaxial silicon layer to an oxide removal process in an oxygen-free environment.

In some embodiments, the oxide removal process comprises at least one of wet etching, chemical treatment, and low energy plasma treatment.

In some embodiments, bonding the first and second sensor wafers is performed in an oxygen-free environment and at a temperature of no more than 450° C.

In some embodiments, the method further includes annealing the integral sensor wafer under high vacuum, in an inert environment, or in reducing environment to prevent oxide formation.

In some embodiments, the method further includes removing the temporarily bonded first carrier wafer from the integral sensor wafer to expose the first sensor structure, forming metal contacts on the first sensor structure, dicing the integral sensor wafer to form sensor chips, connecting a packaging substrate by connecting the metal contacts to circuitry on the packaging substrate and, in some embodiments, using epoxy as an underfill, and removing the temporarily bonded second carrier wafer to expose the second sensor structure.

In some embodiments, the first sensor structure includes an imaging pixel region and signal processing circuitry, and the second sensor structure includes light sensitive device structure.

In some embodiments, the light sensitive device structure includes an amorphous boron layer coating having a thickness of no more than 20 nm.

In some embodiments, at least one anti-reflection layer is disposed on the amorphous boron layer coating.

According to another aspect, the present disclosure is directed to a method of fabricating an image sensor. In embodiments, the method includes forming a first epitaxial silicon layer on a first silicon wafer substrate forming a first sensor structure on a front side of the first epitaxial silicon layer, temporarily bonding a first carrier wafer to the front side of the first epitaxial silicon layer, thinning the first silicon wafer substrate to expose a back side of the first epitaxial silicon layer, polishing the back side of the first epitaxial silicon layer to obtain a flat bonding surface, forming a second epitaxial silicon layer on a second silicon wafer substrate, forming second sensor structure on a front side of the second epitaxial silicon layer, temporarily bonding a second carrier wafer to the front side of the second epitaxial silicon layer, thinning the second silicon wafer substrate to expose a back side of the second epitaxial silicon layer, polishing the back side of the second epitaxial silicon layer to obtain a flat bonding surface, bonding the back sides of the first and second epitaxial silicon layers to form an integral sensor wafer, removing the first carrier wafer from the integral sensor wafer to expose the first sensor structure, and removing the second carrier wafer from the integral sensor wafer to expose the second sensor structure.

According to a further aspect, the present disclosure is directed to an image sensor, for instance a backside illuminated image sensor, including a first epitaxial silicon layer including first sensor structure positioned on a front side of the first epitaxial silicon layer, a second epitaxial silicon layer including second sensor structure positioned on a front side of the second epitaxial silicon layer, and a bonding interface formed between a back side of the first epitaxial silicon layer and a back side of the second epitaxial silicon layer, the bonding interface having no more than a 3 nm thickness of polycrystalline or amorphous silicon.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures in which:

FIG. 1 illustrates schematically a method for processing a frontside sensor wafer on a first carrier wafer, in accordance with one or more embodiments of the present disclosure;

FIG. 2 illustrates schematically a method for processing a backside sensor wafer on a second carrier wafer, in accordance with one or more embodiments of the present disclosure;

FIG. 3 illustrates schematically a method for oxide-free wafer bonding the frontside and backside sensor wafers, in accordance with one or more embodiments of the present disclosure;

FIG. 4 illustrates schematically a method for removing the second carrier wafer, in accordance with one or more embodiments of the present disclosure;

FIG. 5 illustrates schematically a method for removing the first carrier wafer, in accordance with one or embodiments of the present disclosure;

FIG. 6 illustrates schematically use of a silicon interposer wafer for the first carrier wafer, in accordance with one or more embodiments of the present disclosure;

FIG. 7 illustrates schematically use of a silicon interposer wafer for the first carrier wafer with individual sensor dies isolated on the wafer layer, in accordance with one or more embodiments of the present disclosure;

FIG. 8 illustrates schematically a UV optimized sensor including a backside optical coating and silicon interposer wafer for the first carrier wafer, in accordance with one or more embodiments of the present disclosure;

FIG. 9 illustrates schematically a UV optimized sensor including a backside avalanche photodiode (APD) and silicon interposer wafer for the first carrier wafer, in accordance with one or more embodiments of the present disclosure;

FIG. 10 illustrates schematically APD backside contact using a via structure, in accordance with one or more embodiments of the present disclosure;

FIG. 11 illustrates schematically via placement on an image sensor chip including APD structure, in accordance with one or more embodiments of the present disclosure; and

FIG. 12 illustrates a metrology system for semiconductor inspection including at least one image sensor according to the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Broadly, the present disclosure is directed to a method for independently fabricating two separate wafers with each wafer embedding part of a sensor structure, and bonding the two fabricated wafers together by an oxide-free wafer bond to form an integral wafer that combines the two partial sensor structures into one fully-functional sensor structure connected by an electronically conductive thin layer of oxide-free bonding layer enabling continuity of charge transport while minimizing signal loss. By independently fabricating the two wafers, each wafer can be fabricated at its optimal process conditions (e.g., at a temperature greater than 450° C.) such that the combined sensor structure can have enhanced sensor capabilities such as quantum efficiency, gain, wavelength range, etc. The two wafers can be fabricated and processed in parallel to maximize throughput production.

In embodiments, a first wafer containing a partial sensor structure and associated circuitry is processed on a first substrate wafer, and the circuitry side is temporarily bonded to a first carrier wafer. Next, the first substrate is thinned on the wafer back side, i.e., on the opposite side of the circuitry, and polished afterwards. A second wafer containing the remaining sensor structure is processed on a second substrate wafer, and the sensor structure side is temporarily bonded to a second carrier wafer. Next, the second substrate is thinned and then polished. The polishing may include chemical mechanical polishing (CMP) to obtain a high surface quality. The polished wafer surfaces on the two wafers may be cleaned ex-situ to remove surface oxides, then loaded into a high vacuum wafer bonding tool and cleaned in-situ to remove any foreign material to expose the native-oxide-free material surface. The cleaning process may also include surface treatments such as in-situ plasma cleaning at low temperature to reduce the crystal defect density of subsequent bonding interfaces. The cleaned surface after treatment is highly chemically active including dangling bonds that are reactive with any elements in contact. While keeping both cleaned wafer surfaces with dangling bonds under high vacuum before residue gases in the vacuum chamber can form a significant foreign layer portion on the surfaces, the two surfaces are brought together in contact with each other under predetermined pressure and temperature for a predetermined amount of time. The dangling bonds form covalent bonds thereby bonding the two surfaces. By bonding the two processed surfaces in-situ, without the presence of oxides, the bonding interface can be made electrically conductive. After bonding, the two partial sensor structures form an integral sensor structure.

In embodiments, the bonded wafer pair may be annealed, for example, under high vacuum, in an inert environment or reducing environment, for instance in N2 or H2 to prevent oxide formation. The annealing process may be performed at low temperature (e.g., no more than 450° C.) to minimize impact of the additional thermal budget on sensor structures, especially in the metallized regions of the sensor. The annealing may be performed to reduce the defect density at the bonding interface. After the annealing is complete, the first carrier wafer on one side of the formed sensor may be removed thereby exposing the underlying sensor structure to incident light. In embodiments, the exposed surface may be subjected to further processing to remove any sacrificial layers.

In image sensors, an amorphous material layer present at the bonding interface may lead to dark current generation and carrier scattering. The formation of such a layer may be the result of the in-situ cleaning process under high vacuum, such as a plasma treatment that can lead to certain thickness of damaged materials or a slight mismatch in crystal orientation during wafer bonding, or due to residual microscopic surface roughness after the CMP process. When the bonding interface is not atomically flat, there may be silicon-silicon bonding under strain which creates defect energy states. As such, it may be necessary to minimize the impact of this amorphous material layer by (1) minimizing the residue roughness of the pre-bonding wafer surfaces, for example achieving a local root mean square (RMS) roughness below 1˜2 Å uniformly on the wafer, (2) minimizing wafer flatness, e.g., using ultra flat substrates to start with or controlling the CMP process to minimize wafer flatness parameters such as total thickness variation (TTV), bow, etc., (3) minimizing the amorphous bonding layer thickness by tuning the cleaning process parameters, and perhaps reducing it to one monolayer or less, (4) minimizing the density of defect energy states by hydrogenation, (5) aligning the crystallographic orientation of the two pre-bonded surfaces to minimize dislocation density, (6) annealing the bonded wafer pairs under high vacuum, inert environment, or reducing environment, (7) placing the bonding interface layer within a carrier transport region with significant enough net doping gradient to create a drift field to minimize the impact of the interface layer on the carrier transport, etc. In embodiments, one or more or any of the above techniques may be implemented to achieve optimal bonding results.

In embodiments, image sensors according to the present disclosure are suitable for use in, for example, semiconductor inspection systems to enable higher signal to noise ratios for detection of ultraviolet (UV), deep ultraviolet (DUV), vacuum ultraviolet (VUV), extreme ultraviolet (EUV), and X-ray wavelengths, and e-beam by processing the ‘active’ sensor layers on separate carrier wafers at optimal conditions.

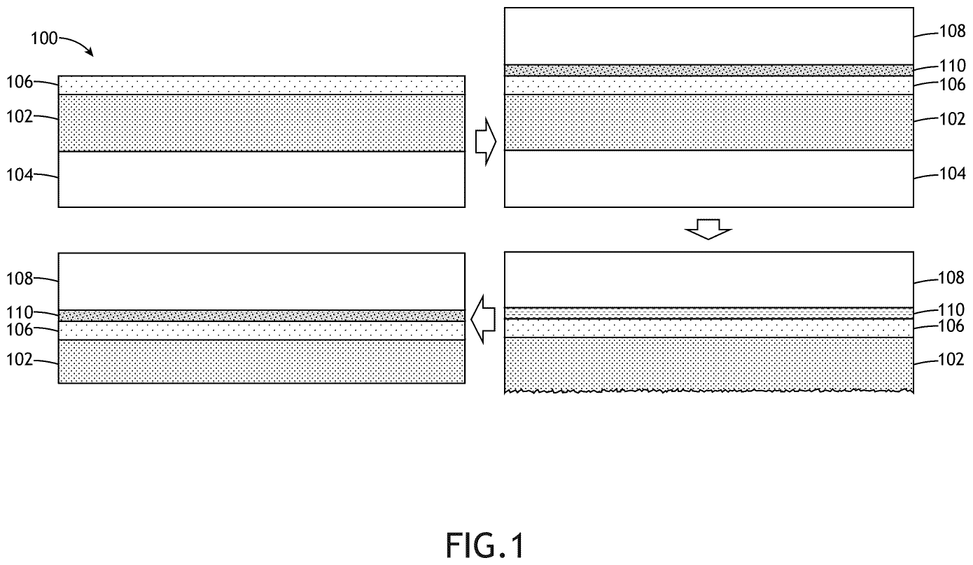

FIG. 1 illustrates schematically fabricating a first 100 or ‘frontside’ sensor wafer. In embodiments, a first epitaxial silicon layer 102 is grown epitaxially on a first silicon wafer substrate 104, for instance an optically flat silicon wafer, and first or ‘frontside’ device structure and associated circuitry 106 are formed on (e.g., processed within and on top of) the first epitaxial silicon layer 102. In embodiments, forming the first device structure and associated circuitry 106 may include ion-implantation, dopant diffusion, annealing, growth/deposition/etching of oxide, nitride, polysilicon, and metals, etc., and patterning (e.g., by lithography), forming both the imaging pixel region configured to collect/store/transfer signal charges resulting from light-to-photo conversion, as well as the frontend of the signal processing circuitry typically including capacitive sensing nodes configured to convert the charges into a voltage, which may then be read out by an amplifier. In embodiments, reset circuitries may also be included to reset the sensing nodes before each signal readout. In embodiments, the first device structure and circuitry 106 may also include output driving circuitry configured to send the voltage or current signals for off-chip signal processing.

Next, the front side of the first epitaxial silicon layer is temporarily bonded to a first carrier wafer 108, for instance adhesively bonded by an adhesion layer 110. In embodiments, the first carrier wafer 108 may be ultra flat but not necessarily atomically smooth at microscopic scales. In embodiments, the adhesion layer 110 may be temporary or permanent. In embodiments, the first carrier wafer 108 may be made of silicon, glass, ceramic, etc. Next, the first sensor wafer is thinned to expose a back side of the first epitaxial silicon layer 102, for example, by a combination of mechanical and/or chemical methods to achieve a first thickness in a range of 5 μm to 100 μm. Finally, the first sensor wafer is further thinned using chemical-mechanical polishing (CMP) to achieve a thickness in a range of 5 μm to 30 μm to achieve an atomically flat surface having a roughness of, for example, <2 Å uniformly across the wafer. The thinned wafer is then cleaned and loaded to a high vacuum preparation chamber in a vacuum wafer bonding tool.

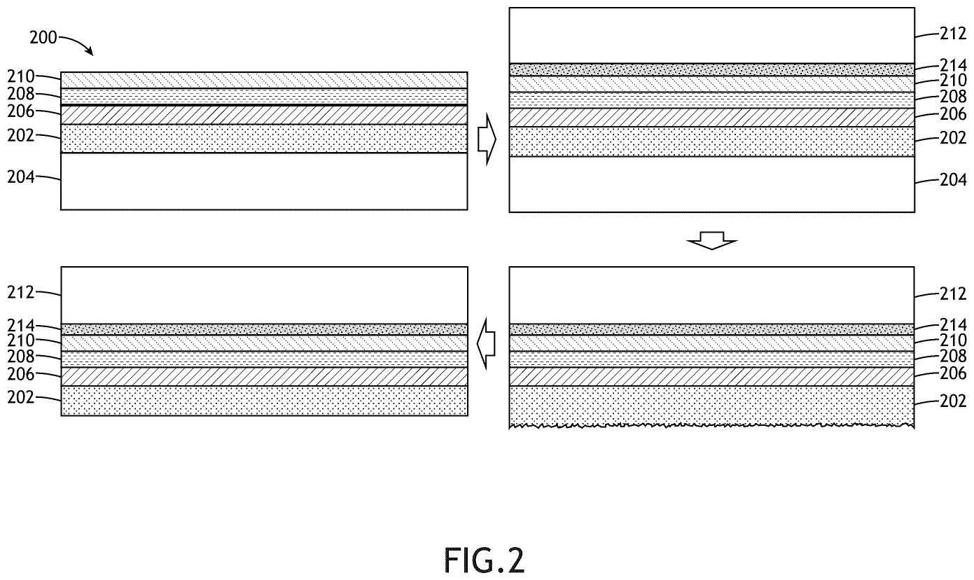

FIG. 2 illustrates schematically fabricating a second or ‘backside’ sensor wafer 200. In embodiments, a second epitaxial silicon layer 202 is grown epitaxially on a second silicon wafer substrate 204, for instance an optically flat silicon wafer, and second sensor structure 206, for example, UV sensitive device structure is formed on top of the second epitaxial silicon layer 202. In embodiments, the second device structure may be formed using ion-implantations and annealing, or deposited/grown using chemical vapor deposition (CVD), atomic layer deposition (ALD), molecular beam epitaxy (MBE), physical vapor deposition (PVD), etc. The second sensor structure 206 may be formed at its optimal process or growth conditions to achieve maximum sensitivity with low dark current and low noise. In one embodiment, the structures for maximizing sensitivity may include a silicon region doped to achieve avalanche multiplication. Next, protective, passivating, and anti-reflective coating (ARC) structures 208 (optionally included) may be deposited followed by a sacrificial layer 210, for instance SiO₂, etc. The sacrificial layer 210 may be removed in a later step by selective etching, stopping at the topmost ARC layer. The UV sensitive structure 206 and any ARC structures 208 may be patterned or unpatterned. In embodiments, the sacrificial layer 210 may cover substantially the entire wafer surface regardless of whether any of the underlying layers are patterned.

Next, the second wafer is bonded to a second carrier wafer 212, such as an ultra-flat silicon wafer, using a temporary adhesion layer 214 that may be removed in a subsequent step. Next, the second sensor wafer is thinned to expose the back side of the second epitaxial silicon layer 202 by mechanically and/or chemically thinning to reach a first thickness in the range of 5 μm to 100 μm with an atomically flat, for example, <2 Å, uniformity across the wafer. Next, the thinned second sensor wafer is further finely thinned using CMP to reach a thickness in a range of 1 μm to 10 μm with an atomically flat surface having a roughness of, for example, <2 Å uniformly across the wafer. The thinned second sensor wafer is then cleaned ex-situ to remove surface oxide build-up using a Fluorine-based related recipe, either wet (e.g., buffered HF) or dry (e.g., SF₆ based plasma), and then loaded into a high vacuum preparation chamber in a vacuum wafer bonding tool.

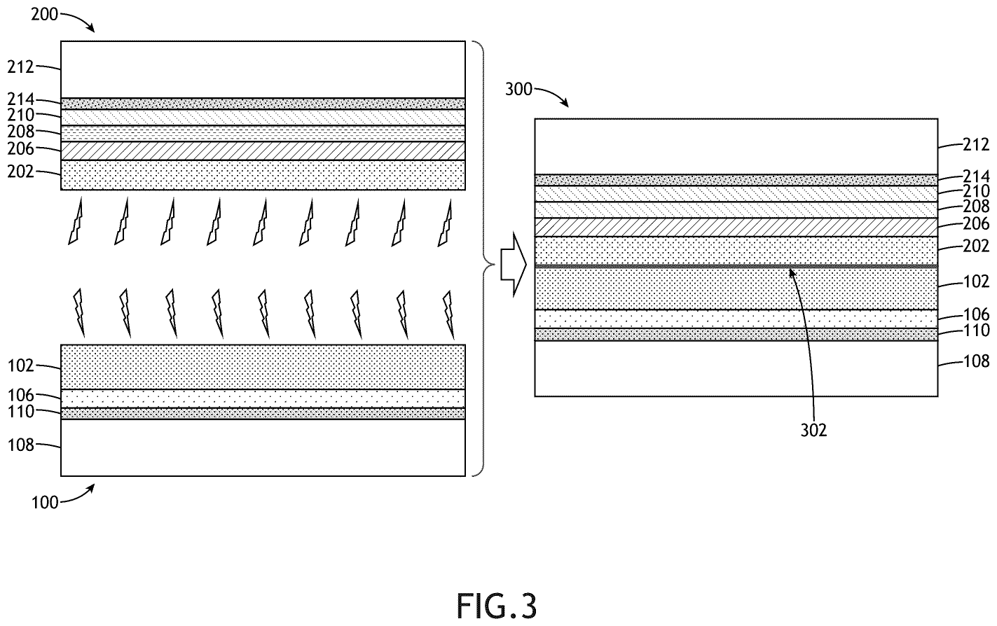

FIG. 3 illustrates schematically oxide-free wafer bonding the first wafer 100 and the second wafer 200. In embodiments, the first wafer 100 and the second wafer 200, previously loaded to the high vacuum chamber in a wafer bonding tool and cleaned, are surface treated to remove the oxide layers natively grown on the surface after the CMP process. In embodiments, the in-situ complete oxide removal process may be performed with a plasma of argon, hydrogen, nitrogen, etc., or with atomic or remote hydrogen at an elevated temperature, typically no more than 450° C. for silicon bonding pairs. In embodiments, the wafer surface may be oriented such that the surface cleaning byproducts have a low probability of getting redeposited onto the sample surface, such as facing the bonding surface vertically or horizontally or inclined depending on the vacuum chamber utilized. In embodiments, the surface oxide may be non-stoichiometric with higher oxygen content on the surface than a few nm below the surface, such that removal of the surface oxide necessitates removal of a few layers (<50 nm) of silicon material with low oxygen concentration.

In embodiments, direct argon plasma treatment may be used to remove the surface oxide layers regardless of oxygen concentration by physically transferring kinetic energy from energetic argon species to the oxide layers, enabling the oxides and native substrate atoms to gain enough energy to break free from the surface. As the required kinetic energy would also lead to underlying lattice distortions, creating an amorphous layer, a subsequent annealing before wafer bonding may be applied to heal the crystalline defects in the amorphous layer and restore the crystalline structure. The annealing may be performed thermally at a temperature no more than 450° C., for example, with a flash lamp or using laser scanning across the bonding surface so that the additional thermal budget on the fabricated sensor components is minimized.

In embodiments, hydrogen plasma may be used to remove the surface oxide by direct reaction of the hydrogen species with the oxide-forming water vapor that can be pumped away. In addition, for silicon-to-silicon bonding pairs, silicon may also react with hydrogen to form gaseous SiHx that can be pumped away. As hydrogen is much lighter in mass than argon, direct kinetic energy transfer may be much smaller than argon plasma, leading to less lattice distortion. However, positively charged hydrogen nuclei may get embedded into the residue oxide layer if not completely removed, leading to a positive fixed charge on the remaining surface after cleaning, which can impede the wafer bonding due to Coulomb repulsion forces between the two positively charged surface.

Remote hydrogen refers to a hydrogen source where hydrogen plasma is generated remotely before the hydrogen species are flown to the location of the wafer to reduce the energetic species in the plasma while maintaining the high reactivity of atomic hydrogen within. Using nitrogen plasma may have similar effect of hydrogen plasma through chemical reaction of oxide with nitrogen radicals forming gaseous NOx that can be pumped away under vacuum. However, it may also form SiₓN_{y} on the surface that would need to be removed in addition, as nitride layers would be insulating at the interface. This may be done, for example, by using argon plasma (such as a mixture of Ar and N₂ plasma). Alternatively, it can be removed in-situ by using reactive ion etching with fluorine-based plasma. In addition, functional plasma such as B₂H₆ may be used to clean and dope the surface at the same time to improve the Ohmic conductivity of the bonded wafer pairs.

To achieve optimal bonding surface quality, a combination of the above techniques may be applied simultaneously or sequentially. For example, mixed Ar/H₂ plasma may be used, while a UV light may be applied at a same time. Sequential argon plasma, H₂ plasma treatment, and atomic hydrogen treatment may be used to mitigate the thickness of the surface amorphous layer. Depending on the wafer configuration of the bonding pair, different in-situ surface cleaning methods may be applied.

Continuing with the bonding step, after both bonding surfaces are cleaned, the bonding surfaces of the first and second epitaxial silicon layers 102, 202 are brought together under high vacuum, for example, at a vacuum level of mid 10⁻⁸ Torr or better, at a temperature ranging from room temperature to no more than 450° C. for silicon bonding pairs, and in some embodiments in an oxygen-free environment. In embodiments, the wafer surface crystal planes may be aligned precisely before the two surfaces are brought together forming covalent bonding. Once bonding is completed, the bonded wafer pair may be annealed under vacuum, inert or reducing ambient, at a temperature ranging from room temperature to no more than 450° C. for a predetermined amount of time required to anneal the bonding interface 302. In other words, allow the silicon at one bonding surface to find the most stable bond with the silicon from the opposing bonding surface in a silicon bonding pair scenario.

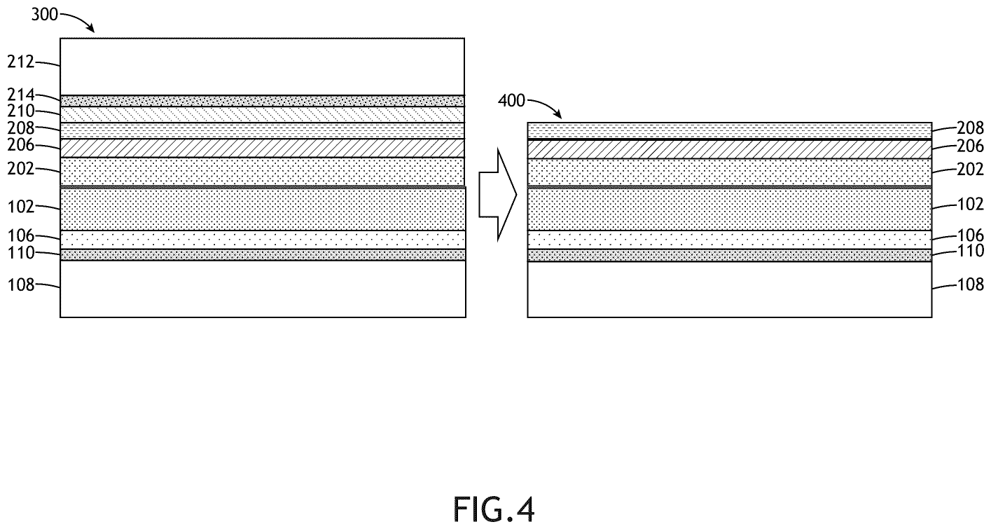

FIG. 4 illustrates schematically for removing the second carrier wafer 212 from the integrally formed first and second sensor wafers 300 to form a modified integral sensor wafer 400. After completion of the oxide-free wafer bonding process according to the bonding process, the second carrier wafer 212 may be directly removed in a debonding tool. Depending on the properties of the temporary adhesion layer 214, the removal process may be a thermal debonding, mechanical debonding, or optical debonding. The adhesion layer is then removed afterwards. The sacrificial layer is then selectively etched away, stopping at the topmost ARC layer 208.

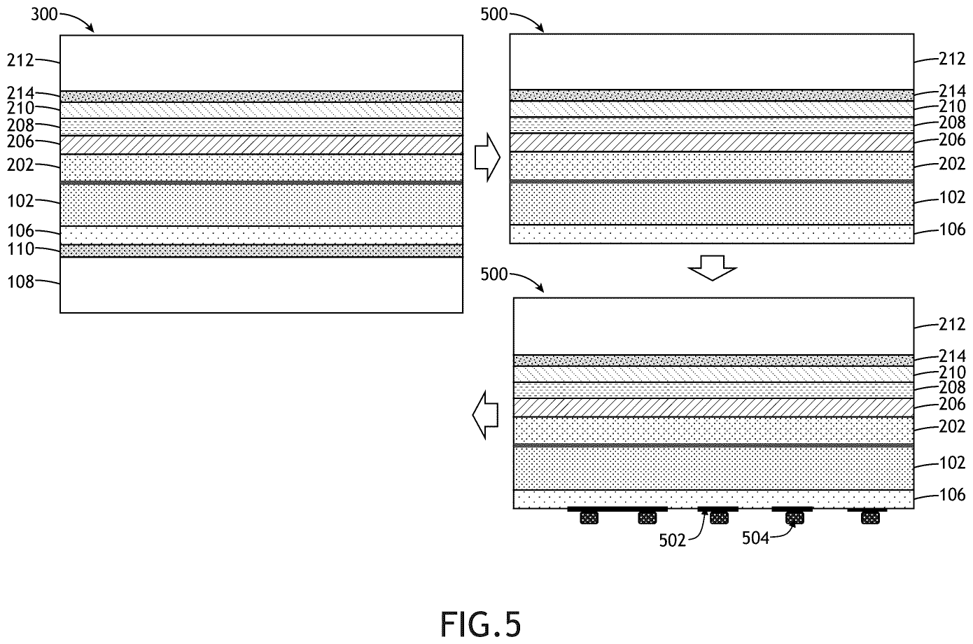

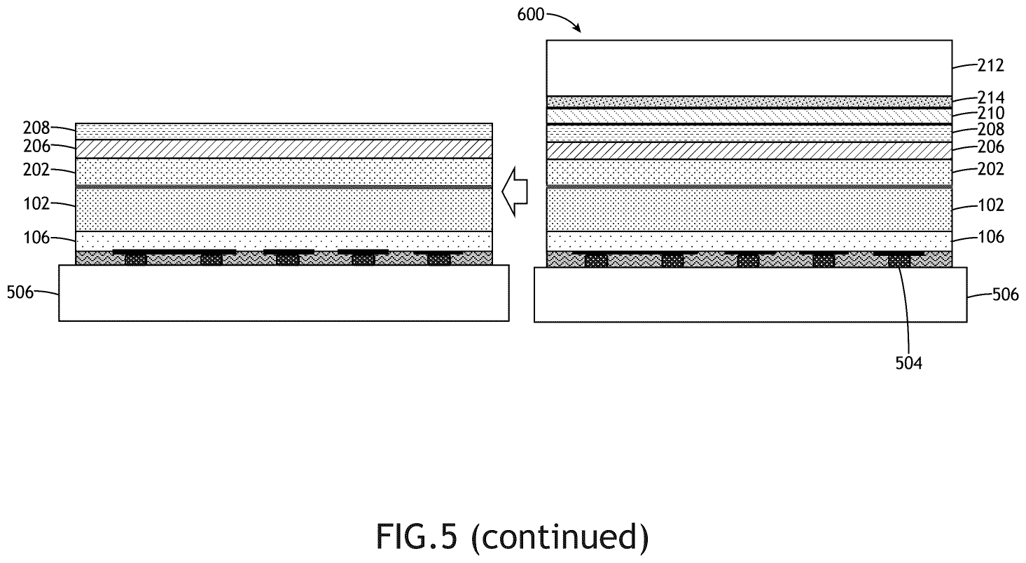

FIG. 5 illustrates schematically another scheme to first remove the first carrier wafer 108 and associated adhesion layer 110 from the integral sensor wafer 300, thereby exposing the frontside circuitry with metal pads 502. Metal contacts 504 (e.g., bumps) are them processed on top of the metal pads 502. The intermediate wafer 500 on the second carrier wafer 212 is then diced and flip-chip bonded to a sensor substrate 506 with wiring that may also incorporate matching metal contacts, and in some embodiments may be connected using epoxy as an underfill. After the die bonding, the second carrier wafer 212 on top of the sensor die is then removed, along with the temporary adhesion layer 214 and the sacrificial layer 210.

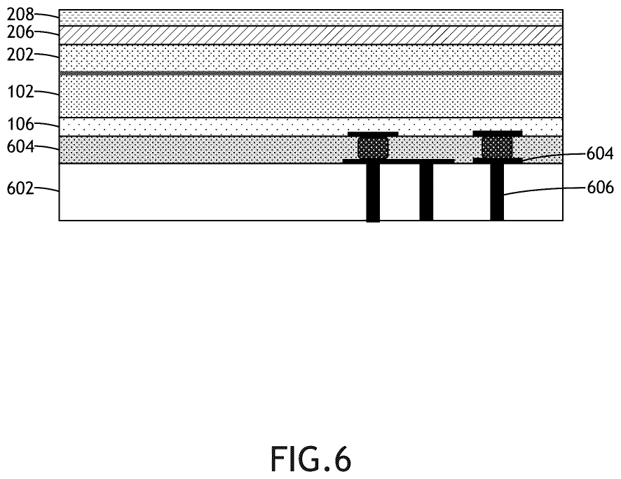

FIG. 6 illustrates schematically a sensor wafer 600 that includes a silicon interposer wafer 602 as the first carrier wafer. In this embodiment, an adhesion layer 604 for bonding the silicon interposer wafer 602 may be permanent. In embodiments, the carrier silicon interposer wafer 602 may include metal traces 606 and through silicon vias 608 (trench etched (TSV)) for connecting one side to the sensor circuitry, and on the other side to backend packaging. The second carried wafer may be removed at the die level to provide a substrate for die bonding without impacting the anti-reflective coating (ARC) 208.

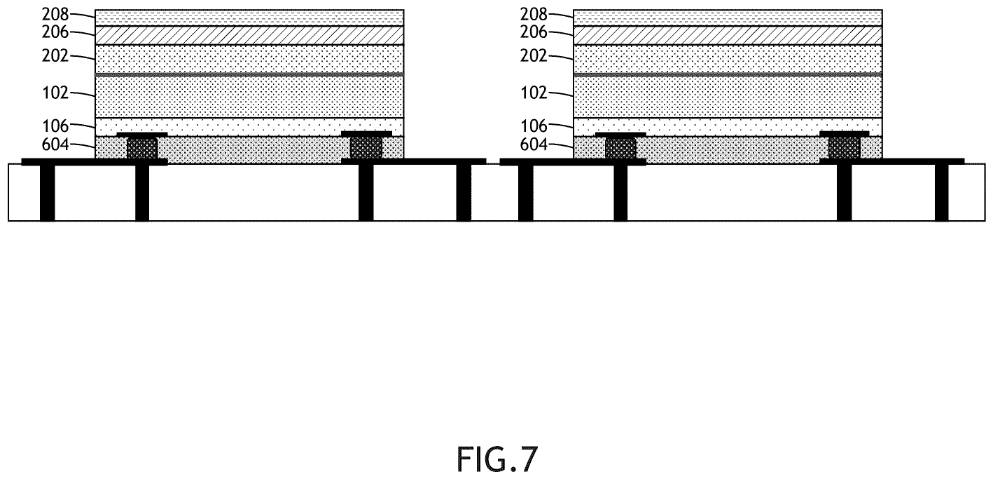

FIG. 7 illustrates schematically a sensor wafer 700 that is a variation of the sensor wafer 600. In this embodiment, the first carrier wafer is removed at the wafer level, followed by a wafer-level die street removal. This creates a tooling access by contacting the interposer wafer 602 on the sensor backside for further die bonding processing. The temporary adhesion layer and the sacrificial layer may be removed on the wafer before dicing the interposer wafer 602 to form individual sensor chips.

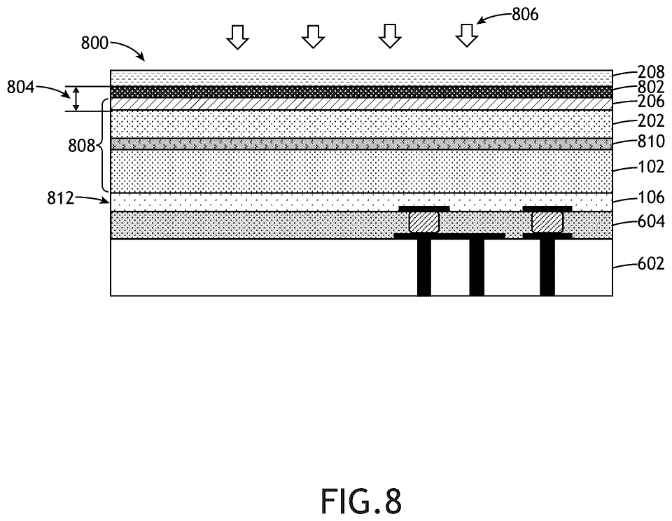

FIG. 8 illustrates schematically of a sensor wafer 800 optimized for UV wavelengths by deposition of an elemental boron layer 802 on top of the Epi-Si (p) 202 (e.g., having a thickness no more than 20 nm). Thermal diffusion at elevated temperatures, for example about 650° C. to about 900° C. prior to the wafer bonding, may be implemented to drive in the boron into a thickness 804 corresponding to the absorption depth of the UV light 806. This creates a built-in drift field for the generated carriers to quickly move away from the surface into the bulk. The thickness of the boron layer 802 may be thick enough to prevent pinhole formation, and thin enough not to absorb too much UV light. The p-doping in the Epi-Si(p) can have a profile, not necessarily uniform, to aid the carrier transport 808. At the vicinity of the bonding interface layer 810, the doping on the two sides may form a doping gradient to assist carriers passing through the interface layer 810 towards the carrier collector 812 on the front side. To minimize the carrier loss across the polycrystalline or amorphous silicon layer, and to be able to establish a drift electric field throughout the entire epi thickness on both sides of the polycrystalline amorphous silicon interface, the polycrystalline or amorphous silicon layer may have a high material quality, such as trap density, carrier lifetime, etc. The amorphousness of the interface layer 810 may within 0-50% to reduce the band edge density of states (i.e., a partially amorphous silicon interface layer).

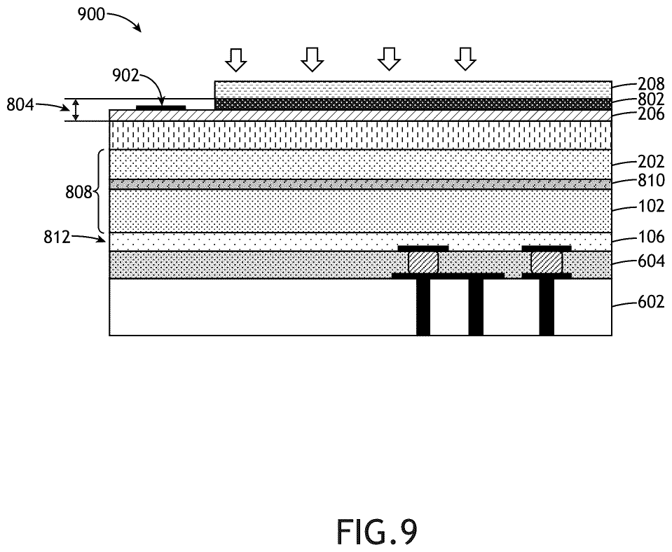

FIG. 9 illustrates schematically a UV optimized sensor wafer 900 similar to sensor wafer 800 but with backside avalanche photodiode (APD) structure for photogenerated carrier transport. In embodiments, APD structure is positioned on the wafer backside while the wafer frontside includes charged-coupled-device (CCD) circuit elements or complementary metal-oxide (CMOS) elements. The APD structure would enable an internal charge signal multiplication enabled by the avalanche effect within the multiplication region 904 where high electric field is present. The APD backside contact 902 may be processed on the wafer before dicing. In embodiments, backside contact 902 may be formed on the wafer by etching away the ARC 208 and boron layers 802 at selected locations, such that the electric field distribution within each sensor region is uniform. For example, to produce a ring structure surrounding the sensor region.

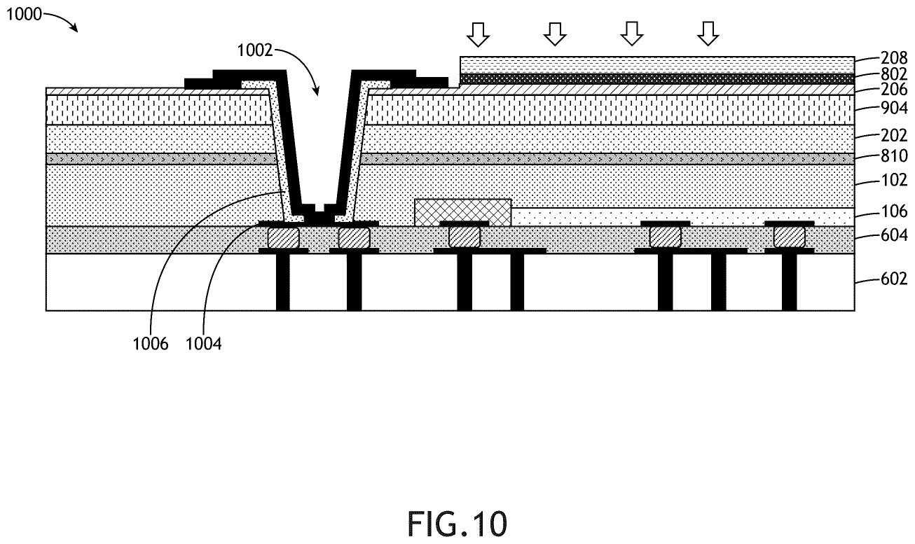

FIG. 10 illustrates schematically a further embodiment of a sensor wafer 1000 including a via structure to enable wafer backside contact in a flip-chip configuration, such as the sensor wafer illustrated in FIG. 9. In embodiments, after the wafer bonding process is completed, vias 1002 may be etched though the wafer 1000 until the frontside contacting pad 1004 is reached. Dielectrics 1006 may be deposited to isolate the APD backside contact 902 from the silicon material. Windows at the bottom of the vias may be opened afterwards. Metal layers may then be deposited to bridge the backside APD contact 902 to the frontside contact pads 1004. In embodiments, sacrificial layers may be used on top of the ARC 208 for the dielectric and metal patterning processes. ARC layers may also be deposited after the APD backside contacts have been made since processing ARC layers may be done at a temperature below 450° C.

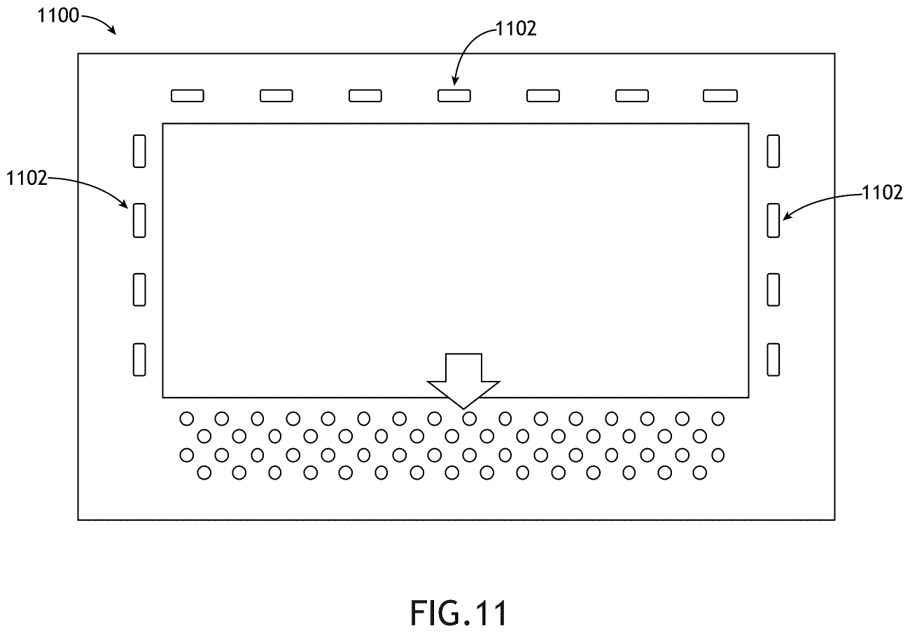

FIG. 11 illustrates schematically an embodiment of via placement on an image sensor chip 1100 with APD structure such as illustrated in FIG. 10. In this embodiment, insulated vias 1102 may be drilled on three sides of the sensor array to maximize the current carrying capacity and spread out the current flow, while allowing the input and output signals on the fourth side. Due to the significant current flow around APD breakdown, it may be necessary to achieve uniform bias, ideally across the entire imaging sensor. For sensors without an APD structure, a similar placement scheme for non-insulated vias may be used to improve the electrical conductivity to the backside surface, especially when high resistive silicon layers are present in the structure.

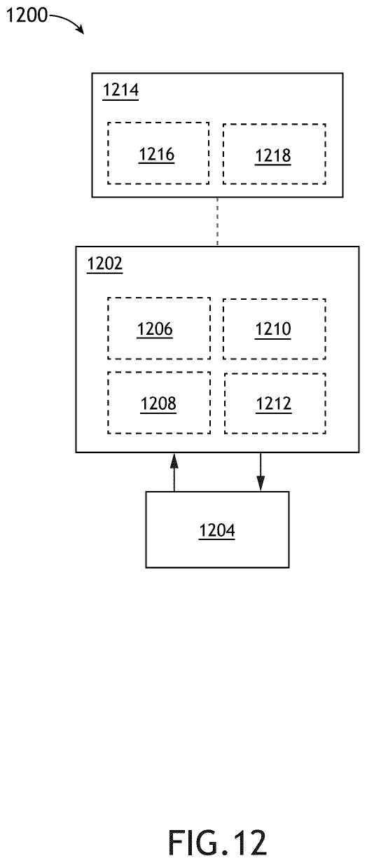

The various wafers described above are suitable for use as image sensors in semiconductor inspection systems to enable higher signal to noise ratios for detection of, for example, UV, DUV, VUV, EUV, and e-beam radiation. FIG. 12 illustrates a non-limiting example of an inspection or metrology system for semiconductor inspection including at least one image sensor according to the present disclosure. In embodiments, the inspection or metrology system 1200 includes an overlay metrology sub-system 1202 to perform overlay measurements of a sample 1204. For example, the overlay metrology sub-system 1202 may perform overlay measurements on portions of the sample 1204 having overlay targets (e.g., grating structures). In other embodiments, the inspection or metrology system 1220 may include a defect detection sub-system 1202.

In embodiments, the defect detection sub-system 1202 includes an illumination sub-system 1206 to generate illumination having a wavelength(s) to illuminate the sample 1204 and a collection sub-system 1208 including at least one image sensor according to the present disclosure to collect light from the illuminated sample 1204. In some embodiments, the defect detection sub-system 1202 may include a translation stage 1210 to scan the sample 1204 through a measurement field of view of the defect detection sub-system 1202 during a measurement to implement scanning inspection. In some embodiments, the defect detection sub-system 1202 may include a beam-scanning sub-system 1212 configured to modify or otherwise control a position of at least one illumination beam on the sample 1204. In embodiments, the defect detection sub-system 1202 is communicatively coupled to a controller 1214 including at least one processor 1216 and memory 1218.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A method for fabricating an image sensor, the method comprising:
fabricating a first sensor wafer including first sensor structure and a temporarily bonded first carrier wafer;
fabricating a second sensor wafer including second sensor structure and a temporarily bonded second carrier wafer;
processing each of the first and second sensor wafers for bonding; and
bonding the first and second sensor wafers by an oxide-free wafer bond to form a sensor wafer.

2. The method of claim 1, wherein the oxide-free wafer bond is configured to transport photogenerated charges from the first sensor wafer to the second sensor wafer.

3. The method of claim 1, wherein at least one of the first sensor wafer and the second sensor is fabricated at a temperature greater than 450° C., and wherein the bonding is performed at a temperature of no more than 450° C.

4. The method of claim 1, wherein fabricating the first sensor wafer comprises:
forming a first epitaxial silicon layer on a first silicon wafer substrate;
forming the first sensor structure on a front side of the first epitaxial silicon layer; and
temporarily bonding the first carrier wafer to the front side of the first epitaxial silicon layer including the first sensor structure,
wherein fabricating the second sensor wafer comprises:
forming a second epitaxial silicon layer on a second silicon wafer substrate;
forming the second sensor structure on a front of the second epitaxial silicon layer; and
temporarily bonding the second carrier wafer to the front side of the second epitaxial silicon layer including the second sensor structure.

5. The method of claim 4, wherein processing the first sensor wafer for bonding comprises:
thinning the first silicon wafer substrate to expose a back side of the first epitaxial silicon layer; and
polishing the back side of the first epitaxial silicon layer to obtain a flat bonding surface,
wherein processing the second sensor wafer for bonding comprises:
thinning the second silicon wafer substrate to expose a back side of the second epitaxial silicon layer; and
polishing the back side of the second epitaxial silicon layer to obtain a flat bonding surface.

6. The method of claim 5, wherein processing the first and second sensor wafers for bonding further comprises subjecting the polished back side of the first epitaxial silicon layer and the polished back side of the second epitaxial silicon layer to an oxide removal process in an oxygen-free environment.

7. The method of claim 6, wherein the oxide removal process comprises at least one of wet etching, chemical treatment, and low energy plasma treatment to remove surface residue.

8. The method of claim 1, wherein bonding the first and second sensor wafers is performed in an oxygen-free environment and at a temperature of no more than 450° C.

9. The method of claim 1, further comprising annealing the sensor wafer under high vacuum, in an inert environment, or in reducing environment to prevent oxide formation.

10. The method of claim 1, further comprising:
removing the temporarily bonded first carrier wafer from the sensor wafer to expose the first sensor structure;
forming metal contacts on the first sensor structure;
dicing the sensor wafer to form sensor chips;
connecting a packaging substrate by connecting the metal contacts to circuitry on the packaging substrate; and
removing the temporarily bonded second carrier wafer to expose the second sensor structure.

11. The method of claim 10, further comprising using epoxy as an underfill to connect the packaging substrate.

12. The method of claim 1, wherein the first sensor structure includes an imaging pixel region and signal processing circuitry, and the second sensor structure includes light sensitive device structure.

13. The method of claim 12, wherein the method further includes doping a portion of the second sensor structure to enable avalanche multiplication of photogenerated carriers.

14. The method of claim 12, wherein the light sensitive device structure includes an amorphous boron layer coating having a thickness of no more than 20 nm.

15. The method of claim 14, further comprising at least one anti-reflection layer deposited on the amorphous boron layer coating.

16. A method of fabricating an image sensor, the method comprising:
forming a first epitaxial silicon layer on a first silicon wafer substrate;
forming first sensor structure on a front side of the first epitaxial silicon layer;
temporarily bonding a first carrier wafer to the front side of the first epitaxial silicon layer;
thinning the first silicon wafer substrate to expose a back side of the first epitaxial silicon layer;
polishing the back side of the first epitaxial silicon layer to obtain a flat bonding surface;
forming a second epitaxial silicon layer on a second silicon wafer substrate;
forming second sensor structure on a front side of the second epitaxial silicon layer;
temporarily bonding a second carrier wafer to the front side of the second epitaxial silicon layer;
thinning the second silicon wafer substrate to expose a back side of the second epitaxial silicon layer;
polishing the back side of the second epitaxial silicon layer to obtain a flat bonding surface;
bonding the back sides of the first and second epitaxial silicon layers to form an integral sensor wafer;
removing the first carrier wafer from the integral sensor wafer to expose the first sensor structure; and
removing the second carrier wafer from the integral sensor wafer to expose the second sensor structure.

17. The method of claim 16, wherein the bonding is performed in an oxygen-free environment and at a temperature of no more than 450° C.

18. The method of claim 16, wherein the first sensor structure includes an imaging pixel region and signal processing circuitry, and the second sensor structure includes light sensitive device structure.

19. The method of claim 16, wherein the first sensor structure includes charged-coupled-device (CCD) circuit elements or complementary metal-oxide semiconductor circuit elements, and the second sensor structure includes device structures and coatings for sensing ultraviolet (UV), deep UV (DUV), vacuum UV (VUV), extreme UV (EUV), and X-ray wavelengths, and e-beam radiation.

20. The method of claim 16, wherein the second sensor structure includes an amorphous boron layer coating having a thickness of no more than 20 nm, and optionally at least one anti-reflection layer deposited on the amorphous boron layer.

21. The method of claim 16, further comprising:
forming metal contacts on the first sensor structure;
dicing the integral sensor wafer to form sensor chips; and
connecting circuitry of a packaging substrate to the metal contacts to connect the packaging substrate to the integral sensor wafer.

22. The method of claim 21, further comprising using epoxy as an underfill to connect the packaging substrate to the integral sensor wafer.

23. The method of claim 16, wherein the method further comprises, prior to bonding the back sides of the first and second epitaxial silicon layers, subjecting the polished back sides of the first and second epitaxial silicon layers to at least one of wet etching for oxide removal, in-situ chemical treatment, and low energy plasma cleaning to remove any surface residue, and to hydrogenation to maintain low defect density at a bonding interface.

24. An image sensor, comprising:
a first epitaxial silicon layer having first sensor structure positioned on a front side of the first epitaxial silicon layer;
a second epitaxial silicon layer having second sensor structure positioned on a front side of the second epitaxial silicon layer; and
a bonding interface positioned between a back side of the first epitaxial silicon layer and a back side of the second epitaxial silicon layer, the bonding interface having no more than a 3 nm thickness of polycrystalline or amorphous silicon.

25. The image sensor of claim 24, wherein the first sensor structure includes an imaging pixel region and signal processing circuitry, and the second sensor structure includes light sensitive device structure.

26. The image sensor of claim 24, wherein the first sensor structure includes charged-coupled-device (CCD) circuit elements or complementary metal-oxide semiconductor circuit elements, and the second sensor structure includes high sensitivity device structures and coating for sensing ultraviolet (UV), deep UV (DUV), vacuum UV (VUV), extreme UV (EUV), and X-ray wavelengths, and e-beam radiation.

27. The image sensor of claim 26, wherein the coating comprises an amorphous boron coating having a thickness of no more than 20 nm.

28. The image sensor or claim 27, further comprising at least one anti-reflective coating deposited on the amorphous boron coating.

29. The image sensor of claim 24, wherein the first epitaxial silicon layer is connected to an interposer layer by through silicon vias that connect the first sensor structure with circuit elements of a sensor packaging substrate.

30. The image sensor of claim 29, wherein the second epitaxial silicon layer includes a doped structure configured to enable avalanche multiplication of photogenerated carriers.

31. The image sensor of claim 30, wherein the second epitaxial silicon layer includes metal contacts for the avalanche multiplication.

32. The image sensor of claim 31, wherein the metal contacts for the avalanche multiplication on the second epitaxial silicon layer are directly connected to the interposer layer by the silicon vias by a trench etched through the first and second epitaxial silicon layers.

33. An inspection system, comprising:
A defect detection sub-system configured to detect defects on a sample;
an illumination sub-system configured to generate illumination to illuminate the sample;
a collection sub-system including at least one image sensor configured to collect light from the illuminated sample, the at least one image sensor comprising:
a first epitaxial silicon layer having first sensor structure positioned on a front side of the first epitaxial silicon layer;
a second epitaxial silicon layer having second sensor structure positioned on a front side of the second epitaxial silicon layer; and
a bonding interface positioned between a back side of the first epitaxial silicon layer and a back side of the second epitaxial silicon layer; and
a controller communicatively coupled to the illumination sub-system.
